(19) United States
(12) Patent Application Publication
(10) Pub. No.: US 2023/0102283 A1
(43) Pub. Date: Mar. 30, 2023

(54) DISPLAY PANEL AND DISPLAY DEVICE

(71) Applicant: Hubei Yangtze Industrial Innovation Center of Advanced Display Co., LTD., Wuhan (CN)

(72) Inventor: Quanpeng YU, Shanghai (CN)

(21) Appl. No.: 17/652,417

(22) Filed: Feb. 24, 2022

(30) Foreign Application Priority Data
Sep. 30, 2021 (CN) 202111166745.1

(51) Int. Cl. H01L 25/16; H01L 33/48; H01L 33/50; H01L 33/60

(52) U.S. Cl. CPC H01L 25/167; H01L 33/483; H01L 33/505; H01L 33/60; H01L 33/507

(57) ABSTRACT

The present disclosure provides a display panel, including: a first barrier wall, enclosing a plurality of first barrier wall openings; light-emitting devices, arranged corresponding to the plurality of first barrier wall openings; and color conversion units, including at least one color conversion unit being at least partially located in a corresponding first barrier wall opening, and at least partially beyond the corresponding first barrier wall opening. The present disclosure also provides a display device. Through the present disclosure, display effect of the display panel can be improved.

### CROSS-REFERENCE TO RELATED APPLICATION

This application claims the priority of Chinese Patent Application No. CN202111166745.1, filed on Sep. 30, 2021, the entire contents of all of which are incorporated herein by reference.

### FIELD OF THE DISCLOSURE

The present disclosure generally relates to the field of display technologies and, in particular, relates to a display panel and a display device.

### BACKGROUND

With vigorous development of display technologies, high color gamut has become an important development direction. The high color gamut means that a display screen has more colorful colors and stronger color display capabilities. A high color gamut display screen can be realized by methods such as a color conversion method. A color conversion display technology is an innovative semiconductor nanocrystal technology that can accurately transmit light, efficiently improve a color gamut value and viewing angle of a display, make colors purer and brighter, and make color performance more tension. Displays using this technology can not only produce dynamic colors with a wider range of color gamut, but also show real color palettes in image quality, exceeding an existing backlight technology.

For example, use of a QD (Quantum Dot) display technology to achieve color conversion is considered to be one of the most promising methods for display colorization. Quantum dots are extremely tiny semiconductor nanocrystals that are invisible to naked eyes. The quantum dots have a unique characteristic: whenever being excited by light or electricity, the quantum dots emit colored light. This characteristic makes the quantum dots capable to change colors of light emitted by a light source. A quantum dot display panel is a display panel that can use the quantum dots to achieve color display.

Therefore, how to improve display effect of the color display has become a hot research topic at present.

### BRIEF SUMMARY OF THE DISCLOSURE

One aspect of the present disclosure provides a display panel, including: a first barrier wall, enclosing a plurality of first barrier wall openings; light-emitting devices, arranged corresponding to the plurality of first barrier wall openings; and color conversion units, including at least one color conversion unit being at least partially located in a corresponding first barrier wall opening, and at least partially beyond the corresponding first barrier wall opening.

Another aspect of the present disclosure provides a display device, including: a display panel, including: a first barrier wall, enclosing a plurality of first barrier wall openings; light-emitting devices, arranged corresponding to the plurality of first barrier wall openings; and color conversion units, including at least one color conversion unit being at least partially located in a corresponding first barrier wall opening, and at least partially beyond the corresponding first barrier wall opening.

Other aspects of the present disclosure can be understood by those skilled in the art in light of the description, the claims, and the drawings of the present disclosure.

### BRIEF DESCRIPTION OF THE DRAWINGS

To more clearly illustrate the technical solutions of the present disclosure, the accompanying drawings used in the description of the disclosed embodiments are briefly described hereinafter. The following drawings are merely examples for illustrative purposes according to various disclosed embodiments and are not intended to limit the scope of the present disclosure. Other drawings may be derived from such drawings by a person with ordinary skill in the art without creative efforts.

FIG. 1 is a top view of an exemplary display panel according to various embodiments of the present disclosure;

FIG. 2 is a partial cross-sectional view along a direction of A-A in FIG. 1;

FIG. 3 is a cross-sectional view of a display panel designed during a research process;

FIG. 4 is another partial cross-sectional view along the A-A direction in FIG. 1;

FIG. 5 is another partial cross-sectional view along the A-A direction in FIG. 1;

FIG. 6 is another partial cross-sectional view along the A-A direction in FIG. 1;

FIG. 7 is another partial cross-sectional view along the A-A direction in FIG. 1;

FIG. 8 is another partial cross-sectional view along the A-A direction in FIG. 1;

FIG. 9 is another partial cross-sectional view along the A-A direction in FIG. 1;

FIG. 10 is another partial cross-sectional view along the A-A direction in FIG. 1;

FIG. 11 is a partial top view of an exemplary display panel according to various embodiments of the present disclosure;

FIG. 12 is a partial cross-sectional view along a A-A direction in FIG. 11;

FIG. 13 is a partial cross-sectional view along a B-B direction in FIG. 11;

FIG. 14 is a partial top view of an exemplary display panel according to various embodiments of the present disclosure;

FIG. 15 is another partial cross-sectional view along the A-A direction in FIG. 1;

FIG. 16 is another partial cross-sectional view along the A-A direction in FIG. 1;

FIG. 17 is another partial cross-sectional view along the A-A direction in FIG. 1;

FIG. 18 is another partial cross-sectional view along the A-A direction in FIG. 1;

FIG. 19 is another partial cross-sectional view along the A-A direction in FIG. 1;

FIG. 20 is another partial cross-sectional view along the A-A direction in FIG. 1;

FIG. 21 is another partial cross-sectional view along the A-A direction in FIG. 1;

FIG. 22 is another partial cross-sectional view along the A-A direction in FIG. 1; and

FIG. 23 is a schematic structural diagram of an exemplary display device according to various embodiments of the present disclosure.

### DETAILED DESCRIPTION

To make the above-mentioned objects, features and advantages of the present disclosure more obvious and understandable, the present disclosure will be further described below with reference to the accompanying drawings and embodiments.

Specific details are set forth in the following description to fully understand the present disclosure. However, the present disclosure can be implemented in many other ways different from those described herein, and those skilled in the art can make similar generalizations without violating the connotation of the present disclosure. Therefore, the present disclosure is not limited by specific embodiments disclosed below.

Terms used in the embodiments of the present disclosure are only for a purpose of describing specific embodiments, and are not intended to limit the present disclosure. Singular forms of “a”, “said” and “the” used in the embodiments of the present disclosure and appended claims are also intended to include plural forms, unless the context clearly indicates other meanings.

“Upper”, “lower”, “left”, “right”, and other directional words described in the embodiments of the present disclosure are described from an angle shown in the drawings, and should not be construed as limitations of the embodiments of the present disclosure. In addition, in the context, when it is mentioned that an element is formed “on” or “under” another element, the element can not only be formed directly “on” or “under” the another element, but also be formed indirectly “on” or “under” the another element through an intermediate element.

Moreover, the exemplary embodiments can be implemented in various forms, and should not be construed as being limited to the embodiments set forth herein. On the contrary, providing these embodiments makes the present disclosure more comprehensive and complete, and fully conveys the concept of the exemplary embodiments to those skilled in the art. Same reference numerals in the drawings indicate same or similar structures, and thus their repeated description will be omitted. Words expressing position and direction described in the present disclosure are all illustrated by taking the drawings as examples, but changes can also be made according to needs, and the changes made are all included in the protection scope of the present disclosure. The drawings of the present disclosure are only used to illustrate a relative position relationship, and layer thicknesses of some parts are drawn in an exaggerated way for easy understanding. The layer thicknesses in the drawings do not represent a proportional relationship of actual layer thicknesses. In the case of no conflict, the embodiments of the present disclosure and the features in the embodiments can be combined with each other. The drawings of the embodiments in the present disclosure use the same reference numerals. In addition, similarities between the embodiments will not be repeated.

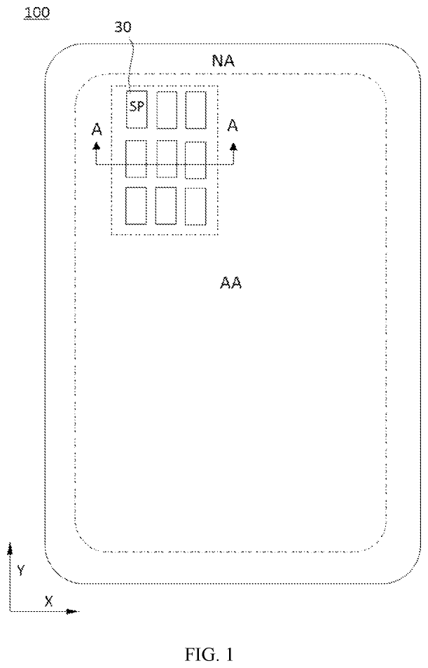

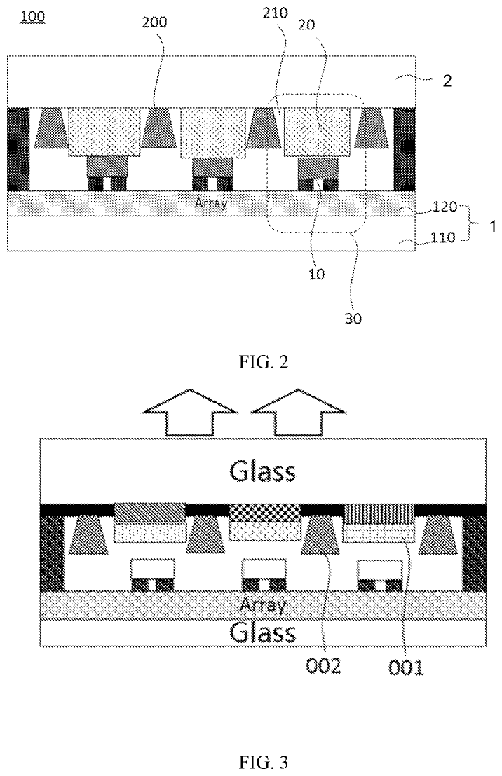

Referring to FIGS. 1 and 2, FIG. 1 is a top view of an exemplary display panel according to various embodiments of the present disclosure, and FIG. 2 is a partial cross-sectional view along a direction of A-A in FIG. 1. The cross-section is perpendicular to a plane where the display panel is located.

Optionally, a display panel 100 is divided into a display area AA and a non-display area NA surrounding the display area AA. A dotted frame in FIG. 1 is used to indicate a boundary between the display area AA and the non-display area NA. The display area AA is an area used by the display panel to display images, and usually includes a plurality of pixel units arranged in an array. Each pixel unit includes a corresponding light-emitting device (for example, a diode), and a control element (for example, a thin film transistor constituting a pixel driving circuit). The non-display area NA surrounds the display area AA, and usually includes peripheral driving components, peripheral wiring, and a fan-out area.

Optionally, the display panel 100 includes a first barrier wall 200 that encloses a plurality of first barrier wall openings 210. Optionally, an orthographic projection of the first barrier wall 200 on a plane where the display panel 100 is located forms a mesh structure, and the first barrier wall openings 210 are equivalent to meshes of the mesh structure.

The display panel 100 further includes light-emitting devices 10, which are arranged corresponding to the first barrier wall openings 210. “Corresponding” here means that orthographic projections of the light-emitting devices 10 overlap orthographic projections of the first barrier wall openings 210 on the plane where the display panel 100 is located, and it does not necessarily mean that the light-emitting devices 10 should also be embedded in the first barrier wall openings 210. Optionally, the orthographic projections of the light-emitting devices 10 on the plane where the display panel 100 is located are within the orthographic projections of the first barrier wall openings 210 on the plane where the display panel 100 is located.

The display panel 100 also includes color conversion units 20. Optionally, the color conversion units 20 include quantum dots. A quantum dot can also be called a nanocrystal grain or nanoparticle, and its particle size is generally between about 1 nm and about 10 nm. Due to quantum confinement to electrons and holes, a continuous energy level structure of the nanoparticle becomes a discrete energy level structure with molecular characteristics, which can emit fluorescence after being excited. An emission spectrum of the quantum dot can be controlled by changing a size of the quantum dot. By changing the size of the quantum dot and its chemical composition, the emission spectrum can cover an entire visible light range, with a wide excitation spectrum and a narrow emission spectrum, so spectrum coverage is relatively high.

In some optional embodiments, the color conversion units include a fluorescent material, such as an organic phosphor.

Optionally, the color conversion units 20 are at least partially located in the first barrier wall openings 210 and at least partially extend beyond the first barrier wall openings 210.

Optionally, the display panel 100 includes a plurality of color conversion units 20, and the color conversion units 20 correspond to the first barrier wall openings 210 in a one-to-one correspondence.

Optionally, a thickness of the color conversion units 20 is greater than a thickness of the first barrier wall 200, and a thickness direction is a direction perpendicular to the plane where the display panel 100 is located.

The color conversion units 20 at least partially extending beyond the first barrier wall openings 210 can be understood as the color conversion units 20 at least partially extending beyond a layer where the first barrier wall openings 210 are located. That is, in a direction parallel to the display panel 100, the color conversion units 20 at least partially do not overlap with the first barrier wall openings 210.

In other words, the color conversion units 20 are at least partially defined in the first barrier wall openings 210, and at a same time, the color conversion units 20 have portions extending from the first barrier wall openings 210 and beyond the first barrier wall openings 210.

In other words, in the direction perpendicular to the plane where the display panel 100 is located, the first barrier wall 200 include opposite upper and lower surfaces, and the color conversion units 20 also include opposite upper and lower surfaces. The upper surface of at least one of the color conversion units 20 is higher than the upper surface of adjacent first barrier wall 200, and/or the lower surface of at least one of the color conversion units 20 is lower than the lower surface of adjacent first barrier wall 200.

To improve display effect of a display panel, although a display screen realized by a color conversion method has more colorful colors and stronger color display ability; however, a technical problem of using a color conversion layer to achieve colorization is that color conversion and light extraction efficiency of a light source exciting the color conversion layer is low. To solve the above technical problem, through the embodiments provided in the present disclosure, a thickness of color conversion units is increased, and an optical path of light emitted by light-emitting devices in the color conversion units is increased, so that the light emitted by the light-emitting devices fully excites the color conversion units, thereby improving the conversion efficiency.

In some optional embodiments of the present disclosure, the color conversion units 20 at least partially extend beyond the first barrier wall openings 210 toward a side of the light-emitting devices 10. In some optional embodiments of the present disclosure, the color conversion units 20 at least partially extend beyond the first barrier wall openings 210 toward a side of a second substrate 2. Because the first barrier wall openings 210 are openings that penetrate the first barrier wall 200, in the direction perpendicular to the plane where the display panel is located, the first barrier wall openings 210 have two ends that communicate with external space. In some optional embodiments of the present disclosure, the color conversion units 20 may simultaneously extend beyond the layer of the first barrier wall 200 from both ends of the first barrier wall openings 210 in the direction perpendicular to the plane where the display panel is located.

Optionally, the display panel 100 includes a plurality of sub-pixels 30 of different colors. The sub-pixels 30 are arranged in an array in the display area AA. A sub-pixel 30 includes a pair of a light-emitting device 10 and a color conversion unit 20 that are disposed oppositely. The sub-pixels 30 of different colors include color conversion units 20 with different light-emitting colors. Incident light can be converted into light of a specific color after passing through a color conversion unit 20, so that a sub-pixel 30 emits light of a corresponding color.

In the embodiments of the present disclosure, the color conversion units 20 included in the sub-pixels 30 of different colors have different light-emitting colors. For example, for a display panel that adopts RGB three-color display technology, a color conversion unit with a red light-emitting color is selected corresponding to a position of a red sub-pixel, a color conversion unit with a green light-emitting color is selected corresponding to a position of a green sub-pixel, and a color conversion unit with a blue light-emitting color is selected corresponding to a position of a blue sub-pixel.

Optionally, the first barrier wall openings 210 define the sub-pixels 30. For example, one first barrier wall opening 210 defines one sub-pixel 30.

In some optional embodiments of the present disclosure, a light-emitting device may be an organic light emitting diode (OLED).

In some optional embodiments, a light-emitting device may be a micro light emitting diode (Micro-LED). A size of the Micro-LED is below about 100 μm. Using the Micro-LED as the light-emitting devices 10 can effectively increase a life of the display panel, reduce power consumption of the display panel, reduce a response time of the display panel, and increase a viewing angle of the display panel.

In the following embodiments of the present disclosure, the light-emitting devices 10 are Micro-LEDs as an example for description.

In some optional embodiments of the present disclosure, when light-emitting devices are provided, light-emitting colors of the light-emitting devices included in sub-pixels of different colors may be consistent. For example, light-emitting devices emitting white light can be arranged at positions of red sub-pixels, green sub-pixels, and blue sub-pixels, and the white light emitted by the light-emitting devices is converted into red light, green light, and blue light respectively through color conversion units of different colors.

Optionally, in some optional embodiments of the present disclosure, for example, light-emitting devices are uniformly blue, and positions of blue sub-pixels do not need to be provided with color conversion units.

Optionally, the display panel 100 further includes a first substrate 1 and a second substrate 2 arranged opposite to each other.

The first barrier wall 200, the light-emitting devices 10, and the color conversion units 20 are located between the first substrate 1 and the second substrate 2.

The light-emitting devices 10 are carried on a side of the first substrate 1 facing toward the second substrate 2.

The first barrier wall 200 is carried on a side of the second substrate 2 facing toward the first substrate 1.

The color conversion units 20 are carried on the side of the second substrate 2 facing toward the first substrate 1.

Optionally, the first substrate 1 includes a substrate 110 and an array layer 120 on a side of the substrate 110 facing toward the second substrate 2. The array layer 120 is on the substrate 110. Alternatively, the array layer 120 includes a plurality of thin film transistors (TFTs) and pixel circuits formed by the thin film transistors for controlling the light-emitting devices 10. The light-emitting devices 10 are disposed on the array layer 120 of the first substrate 1 and are electrically connected to the circuits in the array layer 120 through connection electrodes or eutectic layers.

When the display panel 100 is working, a light-emitting device 10 emits light, and the light emitted by the light-emitting device 10 can emit a corresponding color after being directed to a corresponding color conversion unit 20, so that a corresponding sub-pixel 30 emits light of a preset color. Light of different colors is mixed according to a certain light intensity ratio to produce multiple colors, so that the display panel can realize full-color display. A side where the second substrate 2 is located is a light-emitting side of the display panel 100.

Optionally, the first barrier wall 200 and the color conversion units 20 are manufactured by using the second substrate 2 as a supporting substrate, and then are aligned and attached to the first substrate 1 where LED transfer has been completed.

Optionally, the second substrate 2 may be a cover plate. The second substrate 2 may also include a substrate material, which may be formed of any suitable light-transmitting insulating material, and may be rigid or flexible. The second substrate 2 can be used to protect internal structures of the display panel, and can also be used to block oxygen and moisture. For example, the second substrate 2 may be made of polymer materials, such as polyimide (PI), polycarbonate (PC), polyethersulfone (PES), polyethylene terephthalate (PET), polyethylene naphthalate (PEN), polyarylate (PAR), or glass fiber reinforced plastic (FRP).

Through this embodiment, a first barrier wall and thickened color conversion units are fabricated on a substrate of a same side, so that the first barrier wall can not only serve as an auxiliary support, but also can define the thickened color conversion units. In this way, when the color conversion units are prepared into corresponding defined areas during a preparation process, and then cured by heat or ultraviolet light, because the defined areas are defined by the first barrier wall, thicker color conversion units can be formed. Because of presence of the first barrier wall, uncured color conversion units can also be prevented from overflowing.

To further improve the light conversion efficiency, a thickness of a color conversion layer is set to be thicker, to make the color conversion layer completely absorb light used for excitation. However, it is difficult to further thicken the color conversion layer. As shown in FIG. 3, FIG. 3 is a cross-sectional view of a display panel designed during a research process.

Because a color conversion layer 001 needs to be prepared in a corresponding defined area during a preparation process of the color conversion layer 001, and then cured by heat or ultraviolet rays, because the defined area is defined by structures of a barrier wall 002, uncontrollable overflow of the color conversion layer 001 before curing can be prevented, and color conversion layers 001 correspondingly converting different colors can be spaced apart. If it is desired to increase a thickness of the color conversion layer 001, a thickness of the barrier wall 002 that defines the color conversion layer 001 needs to be increased. However, the thickness of the barrier wall 002 is often positively related to its width. The width is a size of the barrier wall clamped by two adjacent barrier wall openings in a direction parallel to a plane where a display panel is located. In other words, to obtain a higher barrier wall 002, the width of the barrier wall 002 needs to be increased, that is, an area occupied by the barrier wall 002 in the display panel is increased, which results in a need to increase a spacing between light-emitting devices to avoid the barrier wall 002, thereby inevitably sacrificing a certain opening rate.

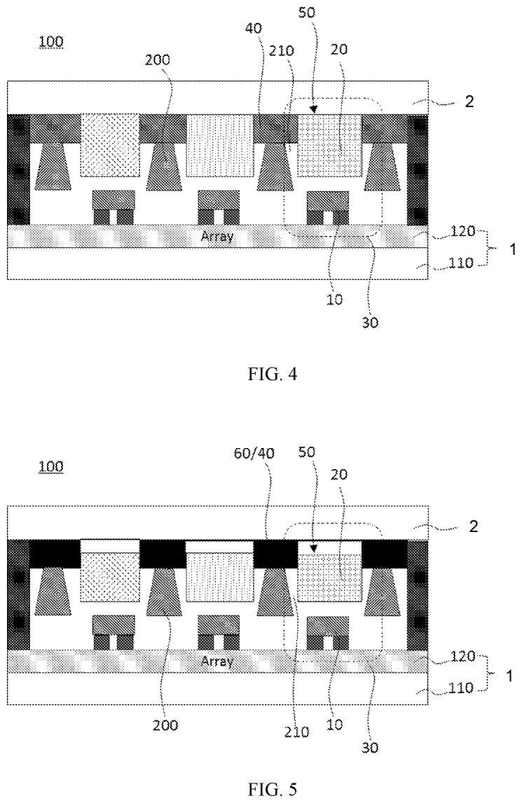

In view of this, in some optional embodiments of the present disclosure, FIG. 4 is another partial cross-sectional view along the A-A direction in FIG. 1, and the cross-section is perpendicular to the plane where the display panel is located.

The display panel 100 further includes a raised portion 40 including blank areas 50 exposing the first barrier wall openings 210, and the color conversion units 20 fill the blank areas 50. In other words, the color conversion units 20 that at least partially extend beyond the first barrier wall openings 210 are at a same layer as the raised portion 40.

Through this embodiment, the blank areas formed by the raised portion provide space for extension of the color conversion units, and at a same time can play a role in defining the thickened color conversion units.

Optionally, the raised portion 40 overlaps the first barrier wall 200.

In this way, the first barrier wall can be raised by the raised portion, which indirectly increases the height of the first barrier wall. While not increasing production difficulty and occupying the area of the display panel, the thickness of the color conversion units is indirectly increased, so as to make light emitted by the light-emitting devices fully excite the color conversion units as much as possible, improve the conversion efficiency, and further improve the display effect of the display panel.

Referring to FIG. 1 and FIG. 5, FIG. 5 is another partial cross-sectional view along the A-A direction in FIG. 1, and the cross-section is perpendicular to the plane where the display panel is located.

The display panel 100 further includes a light shielding layer 60 located on the side of the second substrate 2 facing toward the first substrate 1, and the raised portion 40 multiplexes the light shielding layer 60.

Optionally, the light shielding layer 60 may be a black matrix, that is, a BM. The light shielding layer 60 forms a mesh structure to shield space between the sub-pixels 30. Orthographic projections of meshes of the light shielding layer 60 on the plane where the display panel 100 is located correspond to the first barrier wall openings 210.

Through this embodiment, the raised portion can be multiplexed as the light shielding layer in the display panel, which provides space for increasing the thickness of the color conversion units, and enhances reliability of thickening the color conversion units, while also playing a role to shield a non-sub-pixel area, thereby avoiding light leakage of adjacent sub-pixels or reflection of light from a metal material layer in the non-sub-pixel area.

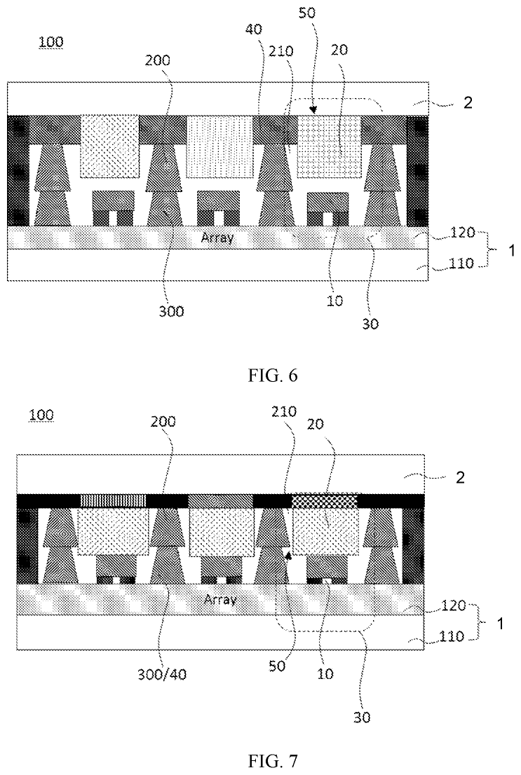

Referring to FIG. 1 and FIG. 6, FIG. 6 is another partial cross-sectional view along the A-A direction in FIG. 1, and the cross-section is perpendicular to the plane where the display panel is located.

The display panel 100 further includes a second barrier wall 300 located on a side of the first barrier wall 200 facing toward the first substrate 1.

Specifically, along the thickness direction of the display panel 100, the first barrier wall 200 and the second barrier wall 300 overlap. In addition, orthographic projections of the first barrier wall 200 and the second barrier wall 300 on the display panel 100 are located at intervals between two adjacent light-emitting devices 10.

Optionally, the second barrier wall 300 encloses a plurality of second barrier wall openings. Optionally, the second barrier wall 300 is similar in pattern to the first barrier wall 200, the orthographic projection of the second barrier wall 300 on the plane where the display panel 100 is located also forms a mesh structure, and the second barrier wall openings are equivalent to meshes of the mesh structure. The second barrier wall can reduce a risk of crosstalk between sub-pixels 30 of different colors in the display panel.

Optionally, at least a portion of the light-emitting devices 10 is located in the second barrier wall openings. The second barrier wall can block the light of the light-emitting devices 10 from entering adjacent sub-pixels, and misfiring color conversion units of the adjacent sub-pixels.

Optionally, the second barrier wall 300 may be formed by using the first substrate 1 as a carrier substrate, or may be formed by using the first barrier wall 200 as a carrier.

Referring to FIG. 1 and FIG. 7, FIG. 7 is another partial cross-sectional view along the A-A direction in FIG. 1, and the cross-section is perpendicular to the plane where the display panel is located.

The display panel 100 further includes a second barrier wall 300 located on a side of the first barrier wall 200 facing toward the first substrate 1.

The raised portion 40 multiplexes the second barrier wall 300.

Optionally, the second barrier wall 300 is formed with the first barrier wall 200 as a carrier, that is to say, after the first barrier wall 200 is completed, the second barrier wall 300 is formed on a side surface of the first barrier wall 200 away from the second substrate 2. After the second barrier wall 300 is formed, the color conversion units 20 are formed.

It is understandable that the first barrier wall 200 and the second barrier wall 300 are not manufactured at a same time. Therefore, the first barrier wall does not increase its width during a patterning process due to process limitation.

Through this embodiment, the raised portion is multiplexed as the second barrier wall, which realizes a function of the above-mentioned second barrier wall without increasing the occupied area of the first barrier wall, and can also provide space for increasing the thickness of the color conversion units.

Optionally, since the first barrier wall 200 and the second barrier wall 300 are not manufactured in a same manner, steps are formed on side walls of a supporting structure formed by the first barrier wall 200 and the second barrier wall 300. For ease of understanding, in the cross-sectional view of FIG. 7, it is shown that a junction of side walls of the first barrier wall 200 and the second barrier wall 300 is not smoothly connected, but has a sawtooth or step-like appearance. In this way, the thickened color conversion units can be better defined, so that the second barrier wall 300 provides space for increasing the thickness of the color conversion units, and at a same time enhances reliability of thickening the color conversion units.

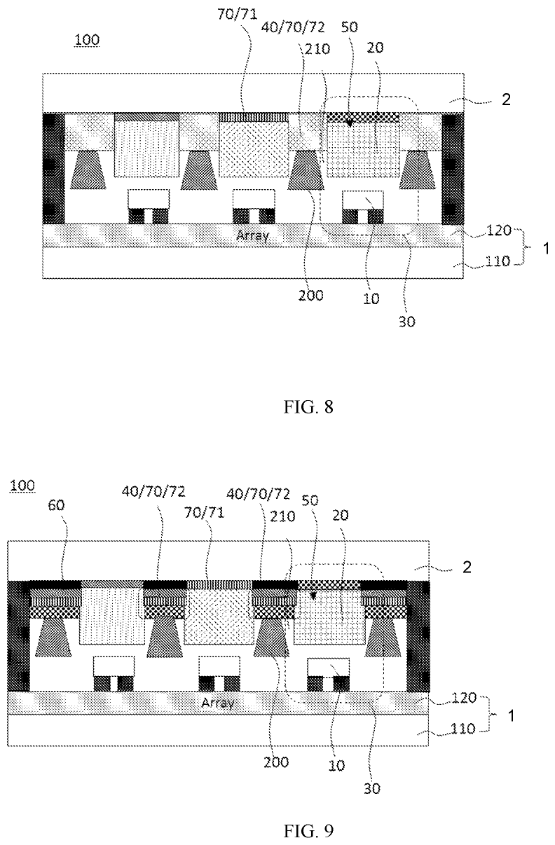

Referring to FIG. 1 and FIG. 8, FIG. 8 is another partial cross-sectional view along the A-A direction in FIG. 1, and the cross-section is perpendicular to the plane where the display panel is located.

The display panel 100 further includes a color resist layer 70 on a side of the second substrate 2 facing toward the first substrate 1.

At least a portion of the color resist layer 70 serves as the raised portion 40.

Optionally, the color resist layer 70 includes main color resists 71 corresponding to the first barrier wall openings 210 and an auxiliary color resist 72.

Optionally, the color conversion units 20 are located on a side of the main color resists 71 facing toward the first substrate 1. In this way, light emitted by a light-emitting device 10 can first pass through a color conversion unit 20, and light excited by the color conversion unit 20 subsequently passes through a main color resist 71 with a corresponding color in a process of continuing to propagate. Setting of the main color resist 71 can color-filter light that is not completely excited by the color conversion unit 20, so as to ensure chromaticity of light emitted from an area of a sub-pixel 30.

It can be understood that a plurality of main color resists 71 respectively forms a plurality of color resist units of different colors, and one color resist unit corresponds to one sub-pixel 30, or one color resist unit corresponds to one first barrier wall opening 210.

Optionally, the auxiliary color resist 72 is located in a space between the sub-pixels 30 to form the raised portion 40.

Optionally, the auxiliary color resist 72 and the main color resists 71 have a same layer and a same material. It should be noted here that the auxiliary color resist 72 and the main color resists 71 being of the same layer and the same material does not necessarily require the auxiliary color resist 72 and the main color resists 71 to be on a same level or on a same plane. The auxiliary color resist 72 and the main color resists 71 being of the same layer and the same material means that the two are formed of same fabrication or made of a same film-forming material.

Through this embodiment, the color resist layer is used as the raised portion, which can provide space for increasing the thickness of the color conversion units without adding additional film layers and processes.

In some optional embodiments of the present disclosure, referring to FIG. 9, FIG. 9 is another partial cross-sectional view along the A-A direction in FIG. 1, and the cross-section is perpendicular to the plane where the display panel is located.

Optionally, the raised portion 40 includes at least two color resist layers 70 with different colors that are stacked to each other. Optionally, the raised portion 40 includes multiple layers of auxiliary color resists 72, and the multiple layers of auxiliary color resists 72 in the raised portion 40 are of a same layer and a same material as main color resists 71 of different colors. That is, the auxiliary color resists 72 of different colors are stacked to form the raised portion 40, thus, the raised portion 40 includes at least two stacked sub-layers allowing to pass different colors.

Through this embodiment, stacking of the auxiliary color resists 72 of different colors can play a role in light shielding, not only further elevating the first barrier wall, to provide more space for increasing the thickness of the color conversion units, and enhance the reliability of the color conversion units, but also at a same time, playing a role in shielding a non-sub-pixel area to avoid light leakage of adjacent sub-pixels or reflection of light from a metal material layer in the non-sub-pixel area.

In some optional embodiments of the present disclosure, the display panel 100 includes the light shielding layer 60 and the color resist layer 70 at a same time. The light shielding layer 60 is equivalent to the black matrix (BM), and openings of the black matrix define the main color resists 71 of the color resist layer 70. A structure formed by the light shielding layer 60 and the color resist layer 70 is equivalent to a color film substrate (or called a color filter (CF)).

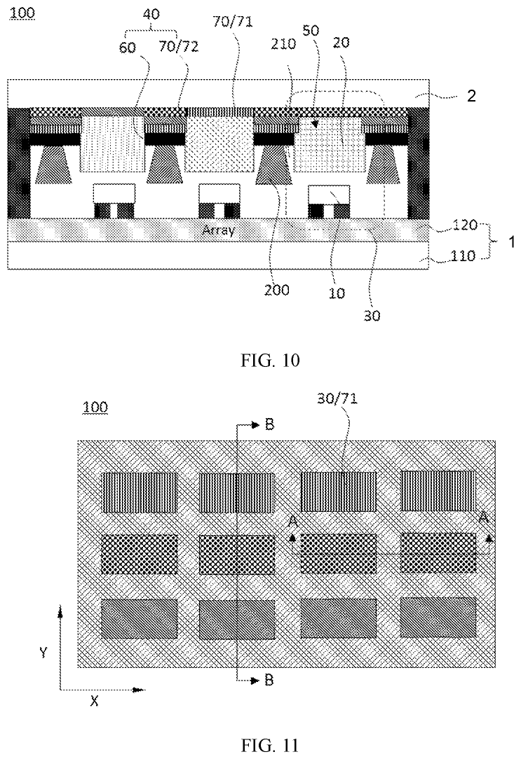

Further optionally, referring to FIG. 10, FIG. 10 is another partial cross-sectional view along the A-A direction in FIG. 1, and the cross-section is perpendicular to the plane where the display panel is located. The raised portion 40 includes the auxiliary color resist 72 and the light shielding layer 60 at a same time, and the auxiliary color resist 72 and the light shielding layer 60 are stacked to each other. Optionally, the light shielding layer 60 is located on a side of the auxiliary color resist 72 facing toward the first substrate 1 or facing toward the light-emitting devices 10. Through this embodiment, a height of the raised portion can be further increased, space is provided for increasing the thickness of the color conversion units, and the light conversion rate is improved. At a same time, light shielding ability of the auxiliary color resist 72 can be improved by the light shielding layer to avoid light leakage.

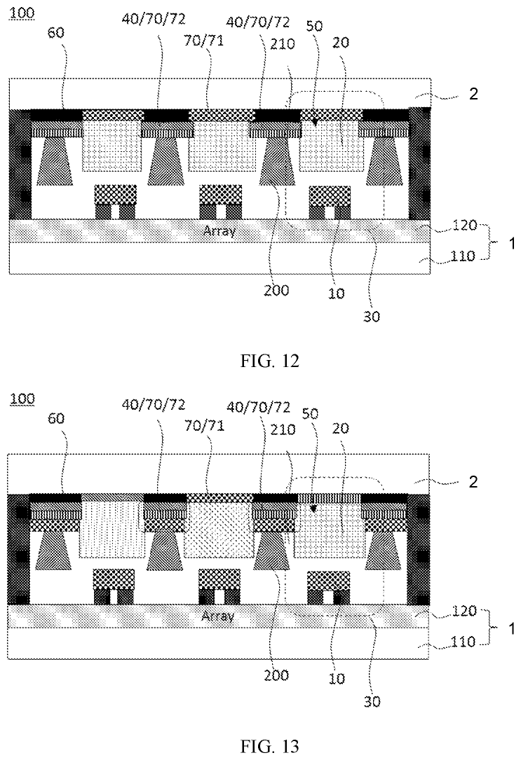

Referring to FIGS. 11 and 12, FIG. 11 is a partial top view of an exemplary display panel according to various embodiments of the present disclosure, FIG. 12 is a partial cross-sectional view along an A-A direction in FIG. 11, and the cross-section is perpendicular to the plane where the display panel is located.

Optionally, the color resist layer 70 includes main color resists 71 corresponding to the light-emitting devices 10 and auxiliary color resists 72 multiplexed as the raised portion 40.

Optionally, in the display panel 100, at least two sub-pixels 30 with a same light-emitting color are arranged adjacent to each other.

Optionally, the display area of the display panel 100 includes sub-pixels 30 arranged in an array along a first direction X and a second direction Y. The first direction X and the second direction Y intersect each other, but both are parallel to the plane where the display panel 100 is located.

Optionally, in this embodiment, the first direction X and the second direction Y are perpendicular to each other. Along the first direction X is defined as a pixel row, and along the second direction Y is defined as a pixel column. Sub-pixels 30 in a same pixel row have a same color. In a same pixel column, sub-pixels of different colors are arranged adjacently. In FIG. 11, sub-pixels with three colors are exemplified, and the sub-pixels with three colors are arranged alternately and cyclically. For example, when the sub-pixels are in three colors of red, green, and blue, in the first direction X, sub-pixels are in one of red, green, and blue, and sub-pixels in the second direction Y are in an order of red, green, and blue, cyclically arranged.

It can be understood that since the main color resists 71 and the sub-pixels 30 have a same light-emitting color, an arrangement of the sub-pixels 30 is consistent with an arrangement of the main color resists 71.

Optionally, a color of the raised portion 40 between adjacent main color resists 71 whose colors are the same to each other is different from the color of the adjacent main color resists 71. That is, a color of the auxiliary color resists 72 located between two adjacent sub-pixels 30 in a pixel row is different from a color of sub-pixels 30 (or main color resists 71) located on both sides of the auxiliary color resists 72 in the first direction. For example, sub-pixels in FIG. 11 are red sub-pixels, then the auxiliary color resists 72 multiplexed as the raised portion 40 between two adjacent red sub-pixels cannot be obtained from a red auxiliary color resist, but can be obtained from a blue auxiliary color resist and a green auxiliary color resist stacked to each other.

Through this embodiment, while meeting sub-pixel arrangement requirements, it is possible to avoid that when one sub-pixel is lit, its adjacent sub-pixels are also lit.

Referring to FIG. 11 and FIG. 13, FIG. 13 is a partial cross-sectional view along a direction B-B in FIG. 11, and the cross-section is perpendicular to the plane where the display panel is located. Similarities between this embodiment and the above-mentioned embodiments will not be repeated. A difference is that although the color resist layer 70 in the embodiment also includes the main color resists 71 corresponding to the light-emitting devices 10 and the auxiliary color resists 72 that are multiplexed as the raised portion 40, but the color of the raised portion between adjacent main color resists whose colors are different is the same as the color of at least one of the adjacent main color resists.

Through this embodiment, the height of the raised portion can be increased as much as possible while meeting the sub-pixel arrangement requirements, so that the thickness of the color conversion units can be indirectly increased, and the conversion efficiency can be improved.

It should be noted that, for ease of understanding, this embodiment uses the pixel arrangement shown in FIG. 11 for specific description, but pixel arrangements of other optional embodiments of the present disclosure are not limited to this.

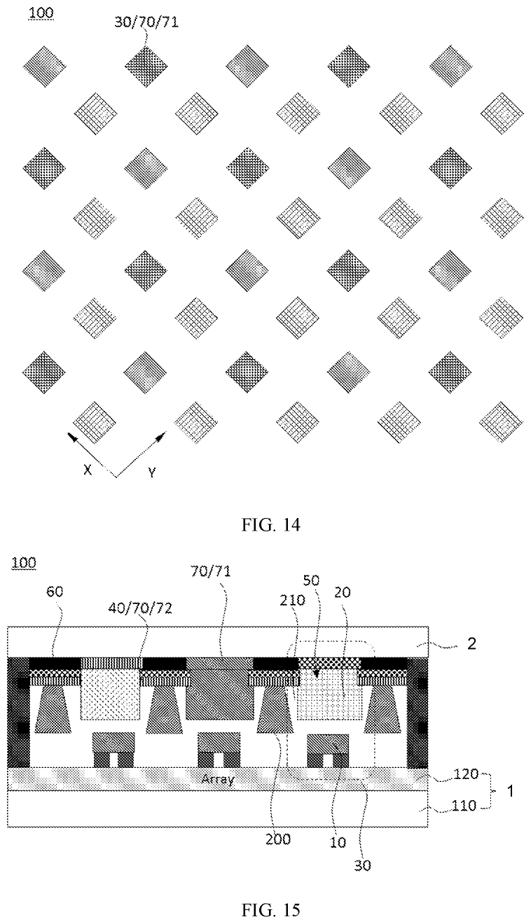

Referring to FIG. 14, FIG. 14 is a partial top view of an exemplary display panel according to various embodiments of the present disclosure, and sub-pixels of different colors of the display panel are arranged adjacently.

It can be understood that since main color resists 71 and sub-pixels 30 have same light-emitting colors, an arrangement of the sub-pixels 30 is consistent with an arrangement of the main color resists 71.

Optionally, the color resist layer 70 includes main color resists 71 corresponding to the light-emitting devices, and main color resists 71 of a same color in the first direction X and the second direction Y are not arranged adjacently.

Optionally, main color resists 71 of different colors are alternately arranged in the first direction X and the second direction Y. For example, when sub-pixels are red, green, and blue, in the first direction X, the sub-pixels are arranged in an order of red, green, and blue, and in the second direction Y, the sub-pixels are also arranged in an order of red, green, and blue.

Through this embodiment, while meeting the sub-pixel arrangement requirements, the height of the raised portion around the sub-pixels can be increased as much as possible, so that structural stability after increasing the thickness of the color conversion units can be improved, and the conversion efficiency can be improved.

Referring to FIG. 1 and FIG. 15, FIG. 15 is another partial cross-sectional view along the A-A direction in FIG. 1, and the cross-section is perpendicular to the plane where the display panel is located.

The light-emitting devices 10 are light-emitting devices of a first color.

Optionally, the raised portion 40 multiplexes a color resist layer 70, but a color of the color resist layer 70 multiplexed by the raised portion 40 is different from the first color. That is, the raised portion 40 does not include the color resist layer 70 that allows the first color to pass.

Optionally, the first color in this embodiment is blue. For example, in some optional embodiments, sub-pixels of the display panel use blue light-emitting devices as light sources, and the blue light-emitting devices are equivalent to the aforementioned light-emitting devices of the first color. Light emitted by the blue light-emitting devices excites red/green quantum dots in a photoconversion film of the color conversion units. After receiving blue light, the red quantum dots excite red light to pass through the color resist layer, the green quantum dots excite green light to pass through the color resist layer, and the blue light directly passes through the color resist layer, to form a full-color display.

Specifically, when the color conversion units 20 include a photochromic quantum dot material, taking light-emitting colors of the color conversion units 20 including quantum dots as red and green as an example, at this time, light-emitting colors of the light-emitting units 10 included in sub-pixels of different colors can be blue light with a greater frequency than red and green light. Under excitation of the blue light, the color conversion units 20 including different quantum dot materials emit red light and green light, respectively. At this time, the color conversion units 20 at positions corresponding to blue sub-pixels in the second substrate 2 may be a transparent material.

Optionally, the raised portion 40 does not include a blue color resist layer 70. Schematically, a same pattern filling in the figure indicates that emitted light has a same color.

Through this embodiment, a color of light allowed by the color resist layer in the raised portion is different from the first color. While the raised portion is multiplexed into other functional structures without adding additional processes, light leakage can be avoided, to prevent crosstalk.

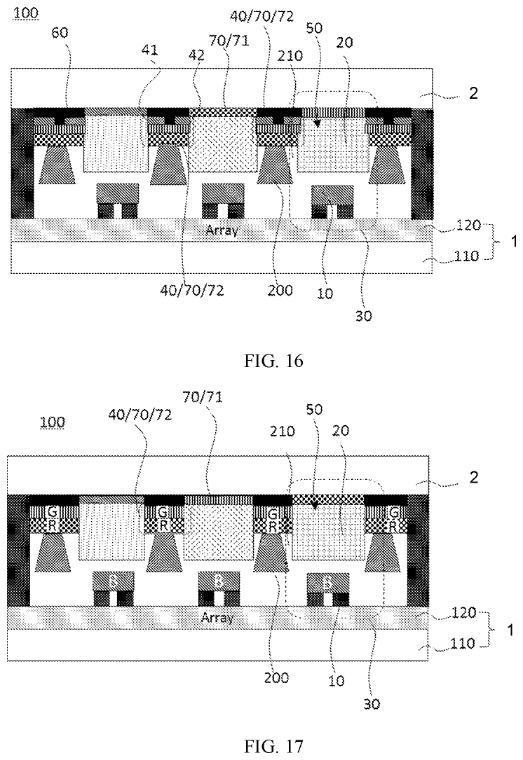

Referring to FIG. 1 and FIG. 16, FIG. 16 is another partial cross-sectional view along the A-A direction in FIG. 1, and the cross-section is perpendicular to the plane where the display panel is located. The light-emitting devices 10 are light-emitting devices of a first color, and other similarities with the previous embodiments will not be repeated in this embodiment. Differently, the raised portion 40 includes a color resist layer 70 that allows the first color to pass through. Along a direction parallel to one of the light-emitting devices 10 pointing to another of the light-emitting devices 10, the color resist layer 70 of the first color in the raised portion 40 includes a first portion 41 and a second portion 42 that are disconnected.

Optionally, the first color in this embodiment is blue.

Optionally, a color resist layer 70 of another color is filled between the first portion 41 and the second portion 42, or a light-shielding material is filled between the first portion 41 and the second portion 42.

Optionally, in some embodiments, the light-shielding material filled between the first portion 41 and the second portion 42 may be a same material as the light shielding layer 60.

Optionally, a layer of the first portion 41 and the second portion 42 is a sub-layer of the raised portion facing toward a side of the second substrate, and is a film layer adjacent to the light shielding layer. Light of the first color emitted by the light-emitting devices can be shielded by other sub-layers of the raised portion, and at a same time, the light shielding layer forming the color filter substrate can be directly multiplexed as the light shielding material filled between the first portion 41 and the second portion 42.

Through this embodiment, the thickness of the raised portion can be further increased, and multiplexing of the raised portion into other functional structures without adding additional processes can also avoid light leakage and prevent crosstalk.

Referring to FIG. 1 and FIG. 17, FIG. 17 is another partial cross-sectional view along the A-A direction in FIG. 1, and the cross-section is perpendicular to the plane where the display panel is located.

A color of a color resist layer 70 on a side of the raised portion 40 facing toward the first substrate 1 and a color of the light-emitting devices 10 are respectively two non-adjacent colors of seven-color rainbow colors.

It should be noted that the seven-color rainbow colors are red, orange, yellow, green, cyan, blue, and purple in order.

Optionally, the raised portion 40 includes multiple color resist layers 70 (or auxiliary color resists 72) stacked in layers, that is, the raised portion 40 includes multiple sub-layers.

Optionally, the color of the color resist layer on the side of the raised portion facing toward the first substrate and the color of the light-emitting devices are colors in the seven-color rainbow colors that are separated by at least two other colors.

Optionally, after colors of the sub-pixels (or the main color resists 71) in the display panel are arranged in sequence according to the seven-color rainbow colors, adjacent colors cannot be used as the color of the color resist layer 70 on the side the raised portion 40 facing toward the first substrate 1 and the color of the light-emitting devices 10.

For example, when the sub-pixels have three colors of red, green, and blue, after arranging the colors of the sub-pixels (or the main color resists 71) in the display panel in sequence according to the seven-color rainbow colors, blue and green are adjacent. Therefore, the color of the color resist layer 70 on the side of the raised portion 40 facing toward the first substrate 1 and the color of the light-emitting devices 10 cannot be blue and green, respectively.

Optionally, the light-emitting devices 10 are light-emitting devices of a first color, and the first color is blue. In this way, color resist layers of at least two colors can be selected for stacking in the raised portion, as long as the color of the color resist layer on the side of the raised portion facing toward the first substrate is selected as red instead of green.

Through this embodiment, light leakage can be avoided and crosstalk can be prevented. For example, blue and green intersect in a visible light waveband, and light at the intersection may leak partly through the raised portion formed by the color resist layers. The design of this embodiment places a red color resist layer at a film position closest to blue light-emitting devices, thereby filtering out the light at the intersection of blue and green, which can prevent crosstalk while taking into account the technical effects of the foregoing embodiments.

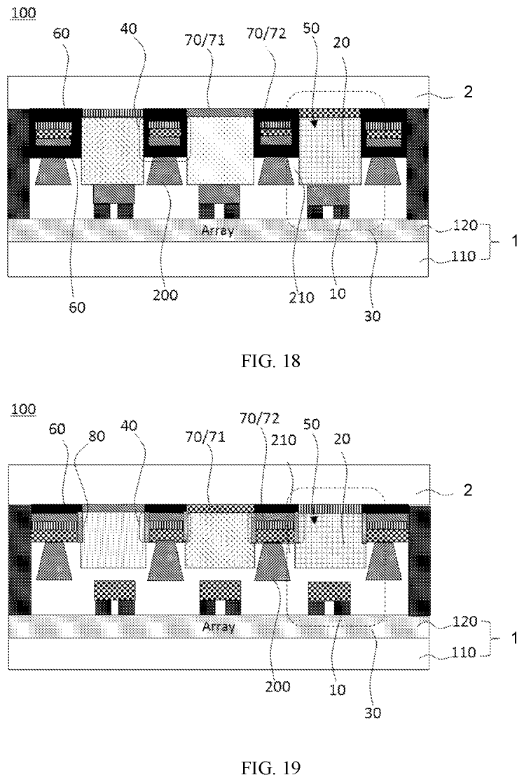

Referring to FIG. 1 and FIG. 18, FIG. 18 is another partial cross-sectional view along the A-A direction in FIG. 1, and the cross-section is perpendicular to the plane where the display panel is located.

Side walls of the raised portion 40 are provided with a light shielding layer 60. That is, the raised portion 40 is covered with the light shielding layer 60 on side surfaces facing toward the color conversion units 20.

In this way, the raised portion can intercept light emitted by light-emitting devices through the light shielding layer even if the light is obliquely emitted.

Optionally, the raised portion 40 includes a color resist layer 70. Optionally, the color resist layer 70 also includes main color resists 71 corresponding to the light-emitting devices 10 and an auxiliary color resist 72 multiplexed as the raised portion 40.

It can be understood that the side walls of the raised portion 40 are provided with the light shielding layer 60, which means that side walls of the auxiliary color resist 72 are provided with the light shielding layer 60.

Optionally, the auxiliary color resist 72 that is multiplexed as the raised portion is of a same layer and a same material as at least one adjacent main color resist.

Through this design, processes can be reduced and cost can be reduced. In addition, because the side walls of the auxiliary color resist are provided with the light shielding layer, even if a color of the auxiliary color resist is the same as a color of main color resists of adjacent sub-pixels, light can be shielded by the light shielding layer, which avoids a situation that light that should be emitted from an area where a certain sub-pixel is located is emitted from another sub-pixel area located nearby.

Furthermore, the light shielding layer 60 encapsulates the raised portion 40. In other words, entire uppermost surface, lowermost surface, and side surfaces of the auxiliary color resist 72 multiplexed as the raised portion 40 are all wrapped by the light shielding layer 60. It is understandable that the light shielding layer 60 encapsulating the auxiliary color resist 72 multiplexed as the raised portion 40 may also be equivalent to forming a portion of the raised portion 40.

Optionally, the raised portion 40 includes a plurality of sub-layers.

In this way, the light shielding layer encapsulates the multiple sub-layers of the raised portion, avoiding separation of film layers, and can further increase the height of the raised portion and at the same time make the raised portion have higher structural stability, which indirectly increases the structural stability of the thickened color conversion units.

Referring to FIG. 1 and FIG. 19, FIG. 19 is another partial cross-sectional view along the A-A direction in FIG. 1, and the cross-section is perpendicular to the plane where the display panel is located.

Side walls of the raised portion 40 are provided with a reflective layer 80, that is, side surfaces of the raised portion 40 facing toward the color conversion units 20 are covered with the reflective layer 80.

Through this embodiment, light emitted by light-emitting devices can be intercepted by the reflective layer even when the light is emitted obliquely, avoiding a situation where light that should be emitted from an area where a certain sub-pixel is located is emitted from another sub-pixel area located nearby. In addition, even if the light emitted by the light-emitting devices is emitted obliquely, it can not only be intercepted by the reflective layer, but also can reflect the obliquely emitted light back into the color conversion units through the reflective layer, and continue to excite the color conversion units, so that the emitted light from the light-emitting devices can be fully utilized, to further improve a problem of low brightness of the display panel.

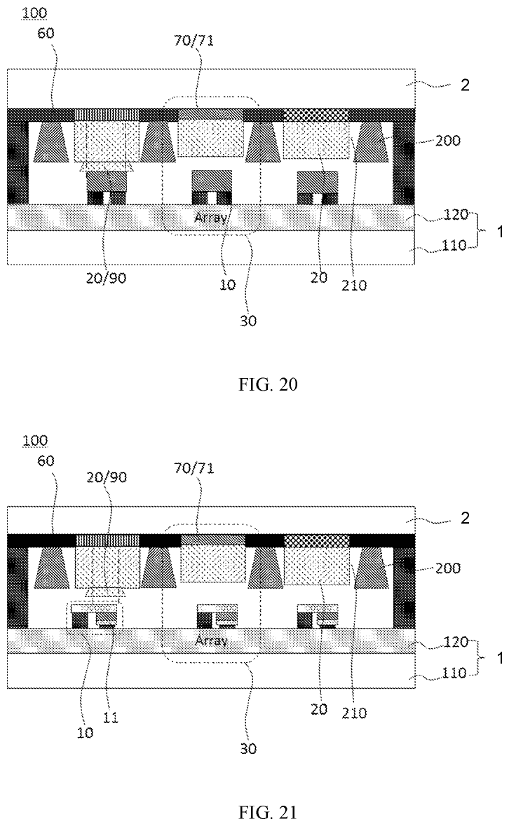

Referring to FIG. 1 and FIG. 20, FIG. 20 is another partial cross-sectional view along the A-A direction in FIG. 1, and the cross-section is perpendicular to the plane where the display panel is located.

Optionally, a portion of a color conversion unit 20 that face toward a light-emitting device 10 beyond a first barrier wall opening 210 is a protruding area 90.

That is, in the direction perpendicular to the plane where the display panel 100 is located, the first barrier wall 200 includes opposite upper and lower surfaces, and the color conversion units 20 also includes opposite upper and lower surfaces. For at least one of the color conversion units 20 opposite to its adjacent first barrier wall 200, the lower surface of the color conversion unit 20 is lower than the lower surface of the adjacent first barrier wall 200. That is, the color conversion units 20 extends toward the light-emitting devices 10. In this way, the color conversion units 20 can be closer to the light-emitting devices 10, and the light emitted by the light-emitting devices 10 can be better utilized.

Referring to FIG. 1 and FIG. 21, FIG. 21 is another partial cross-sectional view along the A-A direction in FIG. 1, and the cross-section is perpendicular to the plane where the display panel is located.

Optionally, a light-emitting device 10 include a light-emitting area 11, and the protruding area 90 overlaps the light-emitting area 11 of the light-emitting device 10.

It can be understood that a light-emitting device 10 include a light-emitting layer and electrode layers located on both sides of the light-emitting layer, and a light-emitting area 11 is an area where the light-emitting layer is located.

Optionally, an area of the protruding area 90 is greater than or equal to an area of the light-emitting area 11.

If a color conversion unit material needs to extend beyond a first barrier wall to increase a thickness, due to side engraving on side of its appearance, an area of a protruding area compared with a portion of a color conversion unit embedded in a first barrier wall opening is small, that is, the protruding area forms a missing portion relative to the color conversion unit embedded in the first barrier wall opening.

Through this embodiment, the missing portion of the color conversion unit beyond the first barrier wall opening can avoid the light-emitting area 11 of the light-emitting device 10 as much as possible, a thickened portion of the color conversion unit can be fully utilized without increasing risks such as residues.

Optionally, a color conversion unit corresponding to a sub-pixel of a first color does not include a protruding area, and a color conversion unit corresponding to a sub-pixel of a second color includes a protruding area. Optionally, the first color is blue or red, and the second color is green. A green picture of a sub-pixel corresponding to a front position of a LED chip turns blue, mainly because after a thickness of a color conversion unit in a green sub-pixel is affected by the first barrier wall, the conversion rate is insufficient compared with color conversion units in other color sub-pixels.

Through this embodiment, a difference between sub-pixels can be compensated while a manufacturing process is easier. When patterning different color conversion units corresponding to different color sub-pixels, etching degree of color conversion units corresponding to first color sub-pixels and etching degree of color conversion units corresponding to second color sub-pixels are controlled to be different and meet the above requirements.

Continuing to refer to FIG. 1 and FIG. 21, optionally, a center of a light-emitting device 10 is offset with respect to a center of a first barrier wall opening 210.

In addition, a light-emitting area 11 of the light-emitting device 10 is made to be as close as possible to the center of the first barrier wall opening.

Optionally, the light-emitting area 11 of the light-emitting device 10 overlaps with the center of the first barrier wall opening as much as possible.

It is understandable that a center of a light-emitting device does not necessarily coincide with a center of a light-emitting area. For example, a LED includes a first area and a second area, and a center of the LED is located between the first area and the second area. Two connecting electrodes of the LED are located in the first area and the second area respectively. The first area includes a first-type semiconductor layer, a light-emitting layer, and a second-type semiconductor layer stacked in sequence, that is, the light-emitting area is in the first area of the LED. The second area is obtained by extending an electrode in a layer of the light-emitting area of the LED away from an array layer or the second-type semiconductor layer in the first area, to connect a connection electrode or a eutectic layer in the array layer.

Through this embodiment, a center of a first barrier wall opening basically coincides with a center of a protruding area, so that a portion of a color conversion unit that extend beyond a first barrier wall opening can be fully utilized as much as possible. For the protruding area with a limited area due to side engraving, utilization of the protruding area is greater without increasing risks such as residuals.

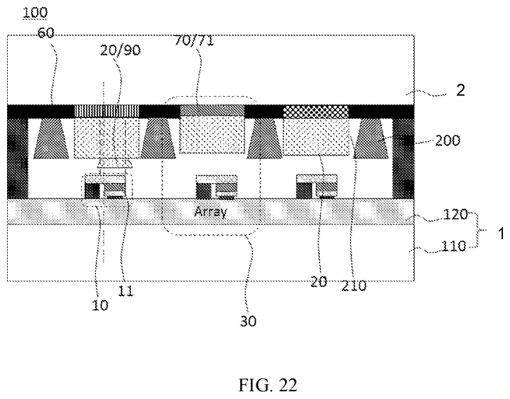

Referring to FIG. 1 and FIG. 22, FIG. 22 is another partial cross-sectional view along the A-A direction in FIG. 1, and the cross-section is perpendicular to the plane where the display panel is located.

Optionally, a center of a protruding area is offset from a center of a first barrier wall opening 210.

In addition, the center of the protruding area can be as close as possible to a light-emitting area 11 of a light-emitting device 10.

Optionally, a color conversion unit may adopt a halfton process, and only a portion beyond a first barrier wall opening and corresponding to the light-emitting area of the light-emitting device 10 is reserved to form the protruding area.

The light-emitting area 11 of the light-emitting device 10 has a serious light leakage with respect to a right side of the first barrier wall opening 210, that is, a right side of a sub-pixel. According to this embodiment, conversion difficulty of the light-emitting device does not need to be increased, while appropriately changing a process and without increasing process difficulty, the portion of the color conversion unit beyond the first barrier wall opening is fully utilized as much as possible, while preventing increase of light leakage, and at the same time not increasing risks such as residues.

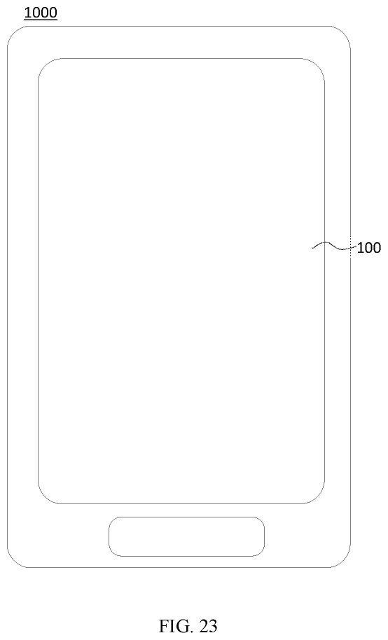

The present disclosure also provides a display device, including the display panel provided by the present disclosure. As shown in FIG. 23, FIG. 23 is a schematic structural diagram of an exemplary display device according to various embodiments of the present disclosure. A display device 1000 includes the display panel 100 provided by any one of the above-mentioned embodiments of the present disclosure. The embodiment of FIG. 23 only uses a mobile phone as an example to describe the display device 1000. It is understood that the display device provided by the embodiments of the present disclosure may be a computer, a TV, a vehicle-mounted display device, and other display devices with display functions. The present disclosure does not impose specific restrictions on this. The display device provided by the embodiments of the present disclosure has the beneficial effects of the display panel provided by the embodiments of the present disclosure. For details, reference may be made to the specific description of the display panel in the foregoing embodiments, and details are not described herein again in this embodiment.

Through the present disclosure, the display effect of the display panel can be improved.

The above description of the disclosed embodiments enables those skilled in the art to implement or use the present disclosure. Various modifications to these embodiments will be obvious to those skilled in the art, and general principles defined herein can be implemented in other embodiments without departing from the spirit or scope of the present disclosure. Therefore, the present disclosure will not be limited to the embodiments shown in this specification, but should conform to the widest scope consistent with the principles and novel features disclosed in this specification.

1. A display panel, comprising:
a first barrier wall, enclosing a plurality of first barrier wall openings;
light-emitting devices, arranged corresponding to the plurality of first barrier wall openings; and
color conversion units, including at least one color conversion unit being at least partially located in a corresponding first barrier wall opening, and at least partially beyond the corresponding first barrier wall opening.

2. The display panel according to claim 1, wherein:
the display panel further includes a first substrate and a second substrate arranged opposite to each other; and
the first barrier wall, the light-emitting devices, and the color conversion units are located between the first substrate and the second substrate, wherein:
the light-emitting devices are carried on a side of the first substrate facing toward the second substrate;
the first barrier wall is carried on a side of the second substrate facing toward the first substrate; and
the color conversion units are carried on the side of the second substrate facing toward the first substrate.

3. The display panel according to claim 1, wherein:
the display panel further includes a raised portion; and
the raised portion includes blank areas exposing the plurality of first barrier wall openings, and the color conversion units fill the blank areas.

4. The display panel according to claim 3, wherein:
the display panel further includes a color resist layer on a side of the second substrate facing toward the first substrate; and
the raised portion multiplexes the color resist layer.

5. The display panel according to claim 4, wherein:
the raised portion includes at least two color resist layers with different colors stacked to each other.

6. The display panel according to claim 4, wherein:
the color resist layer includes main color resists corresponding to the light-emitting devices, and an auxiliary color resist multiplexed as the raised portion; and
a color of the raised portion between adjacent main color resists whose colors are the same to each other is different from the colors of the adjacent main color resists.

7. The display panel according to claim 4, wherein:
the color resist layer includes main color resists corresponding to the light-emitting devices, and an auxiliary color resist multiplexed as the raised portion; and
a color of the raised portion between adjacent main color resists whose colors are different from each other is the same as the color of at least one of the adjacent main color resists.

8. The display panel according to claim 4, wherein:
adjacently arranged sub-pixels have different colors.

9. The display panel according to claim 4, wherein:
the light-emitting devices are light-emitting devices of a first color, and a color of light allowed by the color resist layer in the raised portion is different from the first color.

10. The display panel according to claim 4, wherein:
the light-emitting devices are light-emitting devices of a first color, and the raised portion includes a color resist layer of the first color, wherein the color resist layer of the first color allows light of the first color to pass through; and
along a direction parallel to one of the light-emitting devices pointing to another of the light-emitting devices, the color resist layer of the first color in the raised portion includes a first portion and a second portion that are disconnected.

11. The display panel according to claim 4, wherein:
a color of a color resist layer on a side of the raised portion facing toward the first substrate and a color of the light-emitting devices are respectively two colors of seven-color rainbow colors that are not adjacent to each other.

12. The display panel according to claim 4, wherein:
side walls of the raised portion are provided with a light shielding layer.

13. The display panel according to claim 4, wherein:
side walls of the raised portion are provided with a reflective layer.

14. The display panel according to claim 3, wherein:
the display panel further includes a light shielding layer on a side of the second substrate facing toward the first substrate; and
the raised portion multiplexes the light shielding layer.

15. The display panel according to claim 1, wherein:
the display panel further includes a second barrier wall on a side of the first barrier wall facing toward the first substrate.

16. The display panel according to claim 15, wherein:
the raised portion multiplexes the second barrier wall.

17. The display panel according to claim 1, wherein:
a portion of the color conversion units that extends beyond the plurality of first barrier wall openings toward the light-emitting devices is a protruding area; and
the protruding area overlaps a light-emitting area of the light-emitting devices.

18. A display device, comprising:
a display panel, including:
a first barrier wall, enclosing a plurality of first barrier wall openings;
light-emitting devices, arranged corresponding to the plurality of first barrier wall openings; and
color conversion units, including at least one color conversion unit being at least partially located in a corresponding first barrier wall opening, and at least partially beyond the corresponding first barrier wall opening.
